(19) United States
(12) Patent Application Publication
(10) Pub. No.: US 2008/0169860 A1
(43) Pub. Date: Jul. 17, 2008

(54) MULTICHIP PACKAGE HAVING A PLURALITY OF SEMICONDUCTOR CHIPS SHARING TEMPERATURE INFORMATION

(75) Inventor: Ho Uk Song, Ichon (KR)

Correspondence Address: BAKER & MCKENZIE LLP;PATENT DEPARTMENT, 2001 ROSS AVENUE, SUITE 2300, DALLAS, TX, 75201, US

(73) Assignee: HYNIX SEMICONDUCTOR INC., Ichon (KR)

(21) Appl. No.: 11/966,235

(22) Filed: Dec. 28, 2007

(30) Foreign Application Priority Data
Jan. 11, 2007 (KR) 10-2007-0003222

(51) Int. Cl. H03K 3/42

(52) U.S. Cl. 327/513

(57) ABSTRACT

A multichip package in which characteristics of all semiconductor chips mounted thereon can be controlled in response to a change in temperature. The multichip package can include a substrate and a plurality of semiconductor chips that are sequentially stacked and mounted on the substrate. In this case, a temperature detection circuit may be provided on any one of the plurality of semiconductor chips. The semiconductor chips may be electrically connected to the temperature detection circuit that is provided on any one of the plurality of semiconductor chips, and share temperature data that can be obtained from the temperature detection circuit.

### CROSS-REFERENCES TO RELATED APPLICATION

The present application claims priority under 35 U.S.C. 119(a) to Korean application number 10-2007-0003222, filed on Jan. 11, 2007, in the Korean Intellectual Property Office, the disclosure of which is incorporated herein in its entirety by reference as if set forth in full.

### BACKGROUND

1. Technical Field

The disclosures herein relate to a semiconductor package, and more particularly, to a multichip package that includes a plurality of semiconductor chips sharing temperature information.

2. Related Art

A current electronic industry trend is to manufacture products, which are light weight, small in size, have a fast operation speed, are multifunctional, have excellent performance, and have a high reliability at a low cost. A package assembly technology is one important technology that has been used to enable products to be designed according to the required conditions. A chip scale package (CSP) (or chip size package) as one type of new packages, which is developing in recent years, is advantageous in that the chip scale package has a smaller size than a typical plastic package.

A semiconductor chip scale package has been mainly used in products, such as a digital camcorder, a mobile phone, a notebook computer, and a memory card, which require a small size and excellent portability and mobility. Semiconductor devices, which include a DSP (Digital Signal Processor), an ASIC (Application Specific Integrated Circuit), a microcontroller, and the like, have been mounted in the semiconductor chip scale packages.

Meanwhile, a multichip package or a stacked package has been suggested, in which a plurality of semiconductor chips are stacked while increasing a mounting density per unit of a semiconductor package, but keeping the chip size small to perform a plurality of functions using only one package. This multichip package may include a volatile memory device, for example, a DRAM (Dynamic Random Access Memory), and a non-volatile memory device, for example, a flash memory. Therefore, the multichip package can simultaneously perform a plurality of functions.

A DRAM device that is incorporated in the multichip package includes a temperature detection circuit like a TCSR (Temperature Compensated Self Refresh). The TCSR is a circuit that monitors the temperature in a semiconductor chip and automatically controls a refresh period according to the temperature. In particular, by using characteristics of the DRAM device that has a long data retention period at a low temperature rather than a high temperature, the TCSR lengthens a self refresh period when the DRAM device operates in a low temperature band, and reduces current and power consumption.

Meanwhile, a non-volatile memory device, such as a flash memory device, which is incorporated in the multichip package, does not include a temperature detection circuit unlike the DRAM device. Thus, it is difficult for the non-volatile memory device to appropriately cope with the change in temperature in a semiconductor chip and a package.

As is well known, the flash memory device includes an MOS transistor whose characteristics change in response to a change in temperature. For this reason, in the flash memory device, when a temperature increases, various device characteristics, such as a threshold voltage, may be changed. In particular, in the case of a multichip package that has a plurality of semiconductor chips stacked therein, a calorific value is larger than that in a single package, which makes it difficult to ensure a stable operation in the non-volatile memory device, such as the flash memory device.

When characteristics of a semiconductor chip are deteriorated due to the change in temperature in a package, it affects other normal semiconductor chips. As a result, the entire multichip package performs an erroneous operation or does not operate.

### SUMMARY

A multichip package in which characteristics of all semiconductor chips mounted thereon can be controlled in response to a change in temperature is described herein.

According to one aspect, a multichip package can include a substrate and a plurality of semiconductor chips that can be sequentially stacked and mounted on the substrate. In this case, a temperature detection circuit may be provided on any one of the plurality of semiconductor chips. The semiconductor chips may be electrically connected to the temperature detection circuit that can be provided on any one of the plurality of semiconductor chips, and share temperature data that is obtained from the temperature detection circuit.

According to another aspect, a multichip package can include a printed circuit board, a non-volatile memory semiconductor chip that can be mounted on the printed circuit board, and can include a temperature detection circuit and a first pad, which can be electrically connected to the temperature detection circuit, and a non-volatile memory semiconductor chip that can be mounted on the printed circuit board, and can include a temperature control signal generating unit and a second pad, the temperature control signal generating unit configured to generate a control signal on the basis of temperature data provided by the temperature detection circuit, the second pad being electrically connected to the temperature control signal generating unit. In this case, the first pad and the second pad may be electrically connected to each other by a wiring line. These and other features, aspects, and embodiments are described below in the section entitled “Detailed Description.”

### BRIEF DESCRIPTION OF THE DRAWINGS

Features, aspects, and embodiments are described in conjunction with the attached drawings, in which:

FIG. 1 is a perspective view of a multichip package according to one embodiment.

FIG. 2 is a cross-sectional view of a multichip package according to one embodiment.

FIG. 3 is a cross-sectional view of a multichip package according to another embodiment.

FIG. 4 is a plan view of a multichip package shown in FIG. 3.

FIG. 5 is a schematic block diagram illustrating an internal circuit of a multichip package according to one embodiment.

FIG. 6 is a circuit diagram illustrating a detailed structure of a temperature detection circuit that can be included in the circuit illustrated in FIG. 5.

FIG. 7 is a table illustrating the output of a temperature control signal generating unit of a multichip package according to another embodiment.

FIG. 8 is a table illustrating the output of a temperature control signal generating unit of a multichip package according to another embodiment.

FIG. 9 is a cross-sectional view of a multichip package according to still another embodiment.

### DETAILED DESCRIPTION

A multichip package can include a plurality of semiconductor chips sharing a temperature detection circuit. The temperature detection circuit may be shared by a wire bonding method using pads of the semiconductor chips. The semiconductor chips that constitute the multichip package can operate to correspond to a change in temperature, and the multichip package can prevent an erroneous operation from occurring due to the change in temperature.

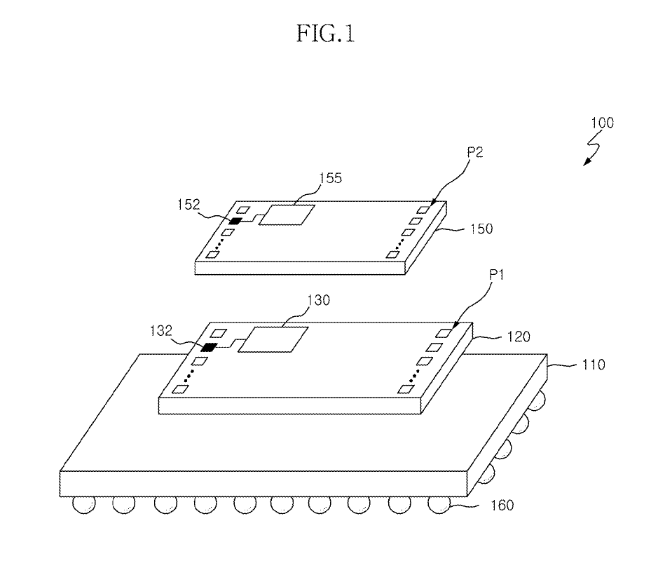

FIG. 1 is a perspective view of a multichip package according to one embodiment described herein. Referring to FIG. 1, a multichip package 100 can include a substrate 110, a first semiconductor chip 120 that can include a temperature detection circuit 130, and a second semiconductor chip 150 that can be stacked on the first semiconductor chip 120.

The substrate 110 can be a printed circuit board where circuit patterns (not shown) can be incorporated. External signal terminals 160, such as conductive balls, which are electrically connected to the circuit patterns to enable the circuit patterns to be connected to an external power supply, may adhere to the bottom of the substrate 110.

The first semiconductor chip 120 can include the temperature detection circuit 130, and may be, for example, a DRAM device. The first semiconductor chip 120 can include a plurality of pads P1 that can be arrayed at an edge to receive signals from the outside of the first semiconductor chip 120. One of the pads P1 can be electrically connected to the temperature detection circuit 130. In one embodiment, for convenience of explanation, a pad connected to the temperature detection circuit 130 is referred to as a temperature detection pad 132.

The second semiconductor chip 150, which can be a different device type from that of the first semiconductor chip 120, may be a non-volatile memory device, such as a flash memory device. The second semiconductor chip 150 can also include a plurality of pads P2 to receive signals from the outside of the second semiconductor chip 150, and a temperature control signal generating unit 155. The temperature control signal generating unit 155 can be configured to receive temperature data from the temperature detection circuit 130 of the first semiconductor chip 120, and generate a signal to control an operation mode, timing, and a voltage level of the non-volatile memory device. The temperature control signal generating unit 155 can be electrically connected to one of the pads P2. In one embodiment, for convenience of explanation, a pad connected to the temperature control signal generating unit 155 is referred to as a temperature transmission pad 152.

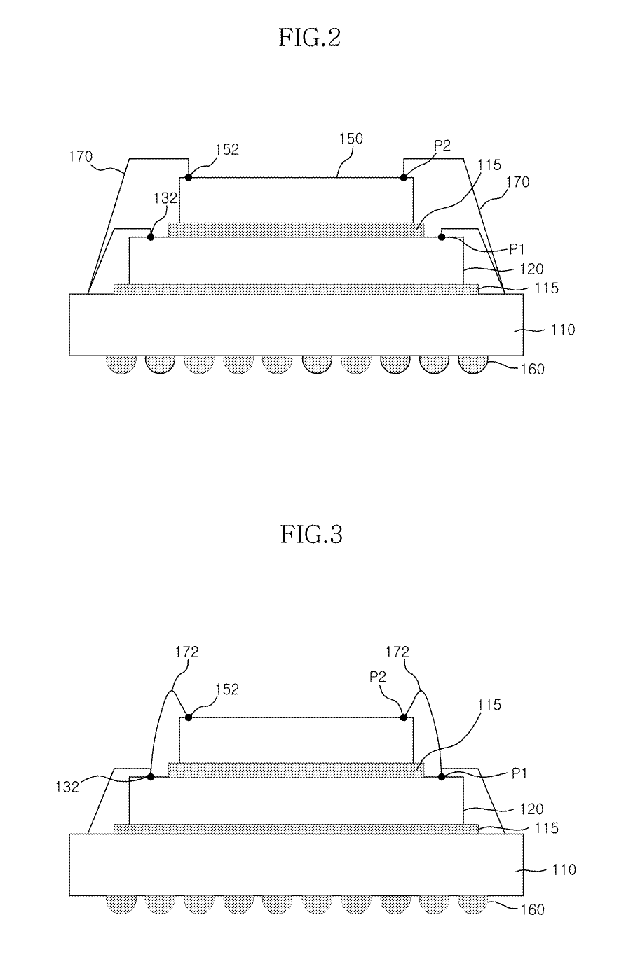

FIG. 2 is a cross-sectional view of a multichip package according to one embodiment described herein. Referring to FIG. 2, the first semiconductor chip 120 can adhere to a top surface of the substrate 110 using an adhesive layer 115. Also, the second semiconductor chip 150 can adhere to a top surface of the first semiconductor chip 120 using the adhesive layer 115. The second semiconductor chip 150 can adhere to the top surface of the first semiconductor chip 120, such that the pads P1, at the edge of the first semiconductor chip 120, are exposed to the outside. The pads P1 of the first semiconductor chip 120 and the pads P2 of the second semiconductor chip 150 are electrically connected to an electrode portion (not shown) of the substrate 110 using wiring lines 170. At this time, the temperature detection pad 132 of the first semiconductor chip 120 and the temperature transmission pad 152 of the second semiconductor chip 150 may be commonly connected to the same electrode portion of the substrate 110.

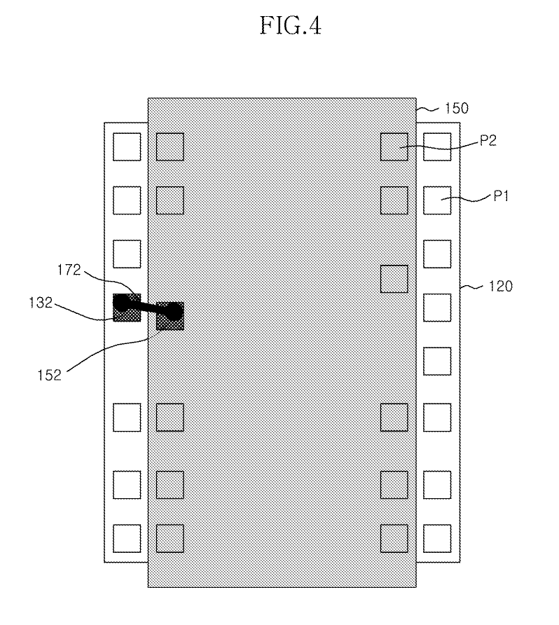

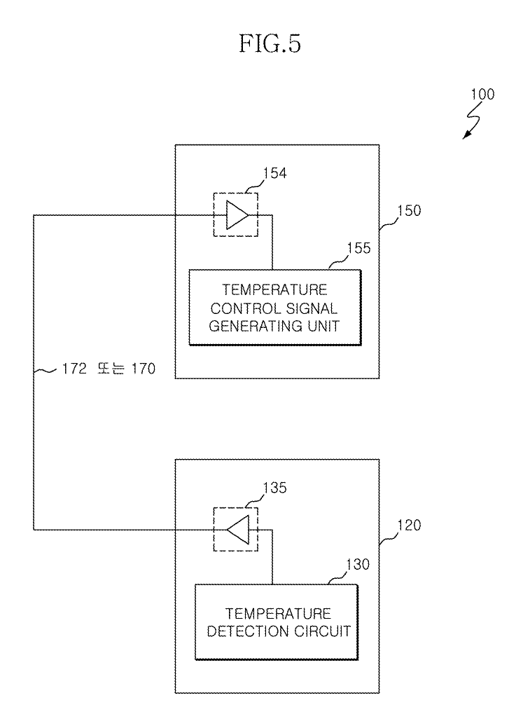

FIG. 3 is a cross-sectional view of a multichip package, and FIG. 4 is a plan view of a multichip package shown in FIG. 3. Referring to FIGS. 3 and 4, the temperature detection pad 132 of the first semiconductor chip 120 and the temperature transmission pad 152 of the second semiconductor chip 150 may be electrically connected to each other by means of a separate wiring line 172.

FIG. 5 is a schematic block diagram illustrating an internal circuit of a multichip package including first and second semiconductor chips according to one embodiment described herein. A multichip package 100 can include a first semiconductor chip 120 that can include a temperature detection circuit 130, a second semiconductor chip 150 that can include a temperature control signal generating unit 155, and a wiring line 172 or 170 that can provide temperature data detected in the first semiconductor chip 120 to the temperature control signal generating unit 155 of the second semiconductor chip 150.

The temperature detection circuit 130 of the first semiconductor chip 120 may be a TCSR (Temperature Compensated Self Refresh) in the case of when the first semiconductor chip 120 is a DRAM device. The temperature detection circuit 130 may include a voltage comparing section 210, an inversion and delay section 220, a control section 230, a temperature detecting section 240, and a temperature detection restricting section 250.

The voltage comparing section 210 can compare a reference voltage and an output voltage of the temperature detecting section 240, and output a voltage level that corresponds to a comparison result. The voltage comparing section 210 can include a voltage distributing unit 212 and a differential amplifying unit 214. The voltage distributing unit 212 can divide a power supply voltage with a predetermined ratio and generate the reference voltage of the voltage comparing section 210. The differential amplifying unit 214 can compare the output voltage (reference voltage) of the voltage distributing unit 212 and the output voltage of the temperature detecting section 240 and output a signal that corresponds to a comparison result.

The inversion and delay section 220 can invert and delay the output signal of the voltage comparing section 210 to ensure a predetermined pulse width of a refresh signal ‘TEMPOSC’. The inversion and delay section 220 can include capacitors C3, C4, and C5 that can maintain the output voltages of a chain of inverters IV1, IV2, and IV3.

The control section 230 can control generation of the refresh signal ‘TEMPOSC’ according to an output signal of the inversion and delay section 220 and an output signal ‘TOSCRSTB’ of the temperature detection restricting section 250 during a refresh signal generation operation using a temperature compensation function. The control section 230 can include a NAND gate ND1 and an inverter IV4 that can invert an output signal of the NAND gate ND1. In this case, the NAND gate ND1 can perform a NAND operation on a temperature detection operation signal ‘TEMPON’, which is always turned on during the refresh signal generation operation using the temperature compensation function, the output signal of the inversion and delay section 220, and the output signal ‘TOSCRSTB’ of the temperature detection restricting section 250.

The temperature detecting section 240 can supply a voltage, which can vary in response to a change in temperature, to the voltage comparing section 210. The temperature detecting section 240 can include a first PMOS transistor PT1, a second PMOS transistor PT2, a first diode D1, a second diode D2, and an NMOS transistor NT1. The first PMOS transistor PT1 can include a gate that can receive the output signal of the control section 230, a source connected to a power supply voltage terminal, and a drain that is connected to an input terminal of the voltage comparing section 210. The first diode D1 may be a MOS transistor (for example, NMOS transistor) whose gate and drain are connected, and is connected between the first PMOS transistor PT1 and the second diode D2. The second diode D2 may be connected between the first diode D1 and the NMOS transistor NT1, and may be, for example, a MOS transistor whose gate and drain are connected. Meanwhile, the second PMOS transistor PT2 can include a gate that can receive the output signal of the control section 230, a source connected to the power supply voltage terminal, and a drain connected to a connecting node n between the first diode D1 and the second diode D2. The NMOS transistor NT1 can be connected between the second diode D2 and a ground terminal, and can be switched according to the output signal of the control section 230.

According to one embodiment displayed in FIG. 5, an output terminal of the temperature detection circuit 130 of the first semiconductor chip 120 may be further provided with an output driver 135 that can buffer the output signal of the temperature detection circuit 130. An input terminal of the temperature control signal generating unit 155 of the second semiconductor chip 150 may be further provided with an input driver 154 that can buffer the signal received from the first semiconductor chip 120.

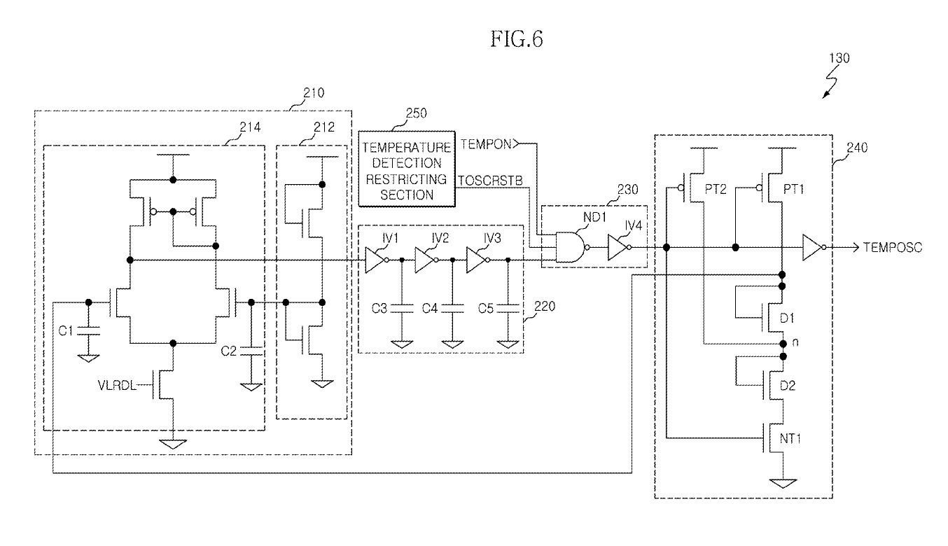

FIG. 6 is a circuit diagram illustrating a detailed structure of a temperature detection circuit that can be included in the circuit illustrated in FIG. 5. The temperature detection circuit that has the above-described structure can operate as follows. First, since a temperature detection operation signal ‘TEMPON’ can be deactivated before performing the temperature compensation function, the control section 230 can output a low signal, and an output terminal of the temperature detection unit 240 can be precharged with a power supply voltage. Therefore, the power supply voltage can be charged in the capacitor C1 of the voltage comparing section 210. At this time, the temperature detection restricting signal ‘TOSCRSTB’ can be maintained at a high level.

Next, if the temperature detection operation signal ‘TEMON’ is activated at a high level, then an output level of the control section 230 can be shifted to a high level. The NMOS transistor NT1 can be turned on, and the temperature detecting section 240 can perform the temperature compensation function. At this time, a voltage drop can be generated at the output terminal of the temperature detecting section 240 because current leakage can be caused by the first and second diodes D1 and D2. In this case, the voltage drop can depend on the amount of current that flows through the first and second diodes D1 and D2. Since the amount of current that flows through the first and second diodes D1 and D2 can change in response to the temperature, the internal temperature of the first semiconductor chip 120 and the internal temperature of the multichip package can be predicted on the basis of the amount of current that flows through the first and second diodes D1 and D2.

The temperature data ‘TEMPOSC’, which can be measured in the temperature detection circuit 130 of the first semiconductor chip 120, can be provided to the temperature control signal generating unit 155 of the second semiconductor chip 150 through the wiring line 172 or 170. Although not shown in the drawings, the wiring line 172 or 170 may have predetermined load resistance that can be determined according to the length thereof. The temperature control signal generating unit 155 can be, for example, a 1-bit logic signal generating unit.

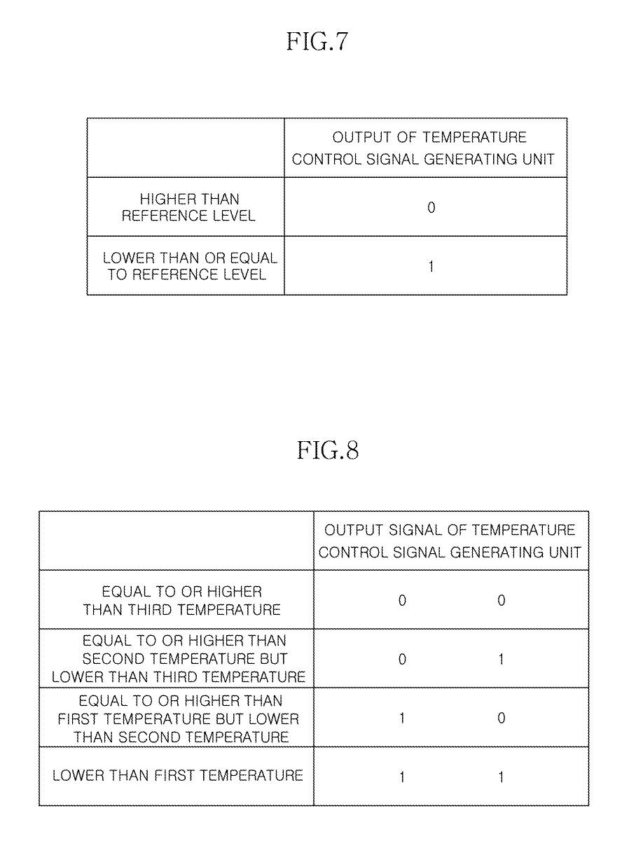

FIG. 7 is a table illustrating the output of a temperature control signal generating unit of a multichip package according to another embodiment. As shown in FIG. 7, the temperature control signal generating unit 155 may be designed similar to a comparator, such that the temperature control signal generating unit 155 can output a low ‘0’ level when a level of the temperature data ‘TEMPOSC’ is higher than a reference level (for example, value that is obtained by converting a predetermined temperature into a voltage), and output a high ‘1’ level when the level of the temperature data ‘TEMPOSC’ is lower than or equal to the reference level. In the case where the temperature control signal generating unit 155 is composed of a 1-bit output comparator, an operation mode, timing, and a voltage level of the second semiconductor chip 150 may be controlled in each of the two temperature intervals. In one embodiment described herein, the reference level is set to about 45° C.

Further, the temperature control signal generating unit 155 may convert the temperature data ‘TEMPOSC’ into a plurality of data bits so as to minutely perform a control operation. Preferably, the temperature control signal generating unit 155 may include a plurality of 2-bit decoders. When the temperature control signal generating unit 155 includes the 2-bit decoders, a temperature range may be divided into four temperature intervals. The four temperature intervals can include a temperature interval lower than a first temperature, a temperature interval equal to or higher than the first temperature but lower than a second temperature, a temperature interval equal to or higher than the second temperature but lower than a third temperature, and a temperature interval equal to or higher than the third temperature (first temperature<second temperature<third temperature). Therefore, it is possible to minutely control the operation mode, the timing, and the voltage level of the second semiconductor chip 150. In one embodiment described herein, the first temperature, the second temperature, and the third temperature may be set to 0° C., 45° C., and 85° C., respectively.

Although not shown in the drawings, the multichip package can then be molded by using an encapsulating material.

According to one embodiment, in the multichip package where the plurality of semiconductor chips are stacked, in the case where the temperature detection circuit is provided on any one of the semiconductor chips, the individual semiconductor chips can be electrically connected to the temperature detection circuit through wire bonding. Therefore, the semiconductor chips that are mounted in the same multichip package can change and control their operation mode, timing, and voltage levels according to the internal temperature, which makes it possible to ensure reliability of the devices.

In one embodiment, the DRAM device can be configured such that the temperature detection circuit and the flash memory device need not have the temperature detection circuit. However, other embodiments may have the temperature detection circuit. Furthermore, other embodiments can include a stacked structure in which various types of semiconductor chips having the temperature detection circuit and semiconductor chips not having the temperature detection circuit are stacked.

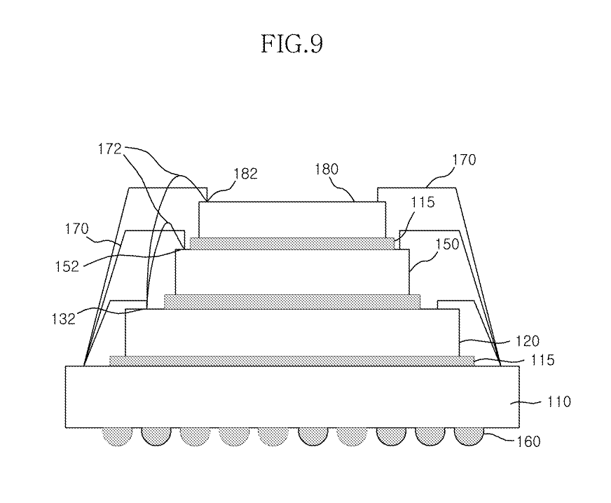

FIG. 9 is a cross-sectional view of a multichip package according to still another embodiment As shown in FIG. 9, a stacked structure can contain three semiconductor chips (or more) stacked, so long as the semiconductor chips are electrically connected to the temperature detection circuit. In FIG. 9, representing one embodiment described herein, reference numeral 180, which is not described above, denotes a third semiconductor chip, and reference numeral 182 denotes a temperature transmission pad of the third semiconductor chip 180.

In one embodiment, the temperature detection circuit can be provided on the first semiconductor chip 120 that can adhere to the top surface of the substrate. The temperature detection circuit may be provided on the second semiconductor chip or the third semiconductor chip. The wiring line can be used to connect each semiconductor chip and the printed circuit board. An equivalent, such as a solder bump, may be used to connect them.

As described in detail above, in the multichip packages where the plurality of semiconductor chips each having different characteristics are stacked, all of the semiconductor chips can be electrically connected to the temperature detection circuit provided on any one of the semiconductor chips by wire bonding, such that the characteristics of the semiconductor chips can be changed according to the internal temperature.

Therefore, characteristics (for example, the operation mode, the timing or the voltage level) of each semiconductor chip can be automatically changed in response to the change in temperature, thereby preventing an erroneous operation from occurring in each semiconductor chip and reducing current and power consumption. Further, since a separate temperature detection circuit does not need to be provided for each semiconductor chip, areas of the semiconductor chips can be reduced. As a result, it is possible to achieve a multichip package that has a light weight and a small size.

While certain embodiments have been described above, it will be understood that the embodiments described are by way of example only. Accordingly, the apparatus and methods described herein should not be limited based on the described embodiments. Rather, the apparatus and methods described herein should only be limited in light of the claims that follow when taken in conjunction with the above description and accompanying drawings.

What is claimed is:

1. A multichip package comprising:
a substrate;
a plurality of semiconductor chips sequentially stacked and mounted on the substrate; and
a temperature detection circuit provided on any one of the plurality of semiconductor chips, wherein the semiconductor chips are electrically connected to the temperature detection circuit and configured to share temperature data obtained from the temperature detection circuit.

2. The multichip package of claim 1, wherein each of the plurality of semiconductor chips includes a plurality of pads, and wherein the semiconductor chip including the temperature detection circuit has a temperature detection pad electrically connected to the temperature detection circuit.

3. The multichip package of claim 2, wherein each of the semiconductor chips without the temperature detection circuit further include a temperature transmission pad that is electrically connected to the temperature detection pad.

4. The multichip package of claim 3, wherein the temperature detection pad and the temperature transmission pad are electrically connected to each other by means of a wiring line.

5. The multichip package of claim 1, wherein the temperature detection circuit includes:
a voltage comparing section configured to compare a voltage varying in response to a temperature and a reference voltage;
an inversion and delay section coupled to the voltage comparing section, wherein the inversion and delay section is configured to invert and delay an output signal of the voltage comparing section;
a temperature detection restricting section configured to generate a restriction signal to compulsorily generate a refresh signal, when the refresh signal is not generated within a predetermined period;
a control section coupled to the inversion and delay section and the temperature detection restricting section, wherein the control section controls generation of the refresh signal according to an output signal of the inversion and delay section and a temperature detection restriction signal, when the refresh signal is generated according to temperature compensation; and
a temperature detecting section coupled to the control section, wherein the temperature detecting section is configured to supply the voltage varying in response to the temperature to the voltage comparing section.

6. The multichip package of claim 1, wherein each of the semiconductor chips not including the temperature detection circuit includes:
a temperature control signal generating unit configured to receive the temperature data provided by the temperature detection circuit and generates a control signal.

7. The multichip package of claim 6, wherein the temperature control signal generating unit is configured to output a low (or high) level when the temperature represented by the temperature data is higher than a reference temperature, and outputs a high (or low) level when the temperature represented by the temperature data is lower than or equal to the reference temperature.

8. The multichip package of claim 7, wherein the temperature control signal generating unit is a 1-bit output comparator.

9. The multichip package of claim 6, wherein the temperature control signal generating unit is configured to divide the temperature data into a plurality of bits to control a plurality of temperature intervals, and output the temperature data.

10. The multichip package of claim 6, wherein the temperature control signal generating unit is a decoder.

11. The multichip package of claim 1, wherein the semiconductor chip including the temperature detection circuit further includes an output driver configured to buffer an output signal of the temperature detection circuit.

12. The multichip package of claim 6, wherein each of the semiconductor chips including the temperature control signal generating unit further includes an input driver configured to buffers data provided by the temperature detection circuit.

13. The multichip package of claim 1, wherein the semiconductor chip including the temperature detection circuit is a DRAM device.

14. The multichip package of claim 13, wherein the temperature detection circuit is a temperature compensated self refresh (TCSR) circuit.

15. The multichip package of claim 1, wherein each of the semiconductor chips not including the temperature detection circuit is a non-volatile memory device.

16. A multichip package comprising:
a printed circuit board;
a volatile memory semiconductor chip mounted on the printed circuit board, wherein the volatile memory semiconductor chip includes a temperature detection circuit and a first pad, which is electrically connected to the temperature detection circuit; and
a non-volatile memory semiconductor chip mounted on the printed circuit board, wherein the non-volatile memory semiconductor chip includes a temperature control signal generating unit and a second pad, wherein the temperature control signal generating unit is configured to generate a control signal on the basis of temperature data provided by the temperature detection circuit, the second pad being electrically connected to the temperature control signal generating unit, and wherein the first pad and the second pad are electrically connected to each other.

17. The multichip package of claim 16, wherein the first pad and the second pad are electrically connected to each other by means of a wiring line.

18. The multichip package of claim 16, wherein the temperature detection circuit is a temperature compensated self refresh (TCSR) circuit.

19. The multichip package of claim 16, wherein the temperature control signal generating unit is configured to output a low (or high) level when the temperature represented by the temperature data is higher than a reference temperature, and output a high (or low) level when the temperature represented by the temperature data is lower than or equal to the reference temperature.

20. The multichip package of claim 16, wherein the temperature control signal generating unit is configured to divide the temperature data into a plurality of bits to control a plurality of temperature intervals, and output the temperature data.
